(19) United States
(12) Patent Application Publication
(10) Pub. No.: US 2012/0195018 A1
(43) Pub. Date: Aug. 2, 2012

(54) Wireless communication device using voltage switchable dielectric material

(76) Inventor: Lex Kosowsky, San Jose, CA (US)

(21) Appl. No.: 11/562,222

(22) Filed: Nov. 21, 2006

Related U.S. Application Data
(60) Provisional application No. 60/739,725, filed on Nov. 22, 2005.
(60) Provisional application No. 60/740,961, filed on Nov. 30, 2005.

(51) Int. Cl. H05K 9/00; B82Y 30/00

(52) U.S. Cl. 361/816; 977/742; 977/932

(57) ABSTRACT

A wireless communication device, such as an RFID tag, is provided material that is dielectric, unless a voltage is applied that exceeds the materials characteristic voltage level. In the presence of such voltage, the material becomes conductive. The integration of such material into the device may be mechanical and/or electrical.

### RELATED APPLICATIONS

This applications claims priority to provisional U.S. Provisional Patent Application No. 60/739,725, filed Nov. 22, 2005, entitled “RFID Tag Using Voltage Switchable Dielectric Material,” the aforementioned application being hereby incorporated by reference in its entirety.

This applications claims priority to provisional U.S. Provisional Patent Application No. 60/740,961, filed Nov. 29, 2005, entitled “Light Emitting Devices With ESD Characteristics,” the aforementioned application being hereby incorporated by reference in its entirety.

### TECHNICAL FIELD

The disclosed embodiments relate generally to wireless communication devices. More specifically, embodiments described herein include a wireless communication device that integrates or incorporates voltage switchable dielectric material.

### BACKGROUND

There are increasingly large number of wireless communication devices and applications. Examples include chip sets and components for cellular communication devices, short-range wireless communications over WiFi (IEEE 802.11 or Bluetooth) and numerous other applications such as radio frequency identification (RFID) tags.

RFID tags are increasingly common means of identifying and tracking objects throughout their lifecycle. The uses of RFID tags are abundant, and mark goods and products in manufacturing, transportation, and distribution. RFID tags are also used for wireless transmission in both military and civilian applications. While RFID tags are effective in their uses, RFID components are fragile. In particular, the tags are susceptible to all types of threats from the outside environment as they are essentially semiconductor devices.

### BRIEF DESCRIPTION OF THE DRAWINGS

FIG. 1 is a block diagram illustrating components for a device that generates radio-frequency identification information, where the device is constructed to include voltage switchable dielectric material, under to an embodiment of the invention.

FIG. 2A illustrates a first section of a radio-frequency identification (RFIFD) tag device in which voltage switchable dielectric material is provided, under an embodiment of the invention.

FIG. 2B illustrates a second section of an RFID tag device as shown in FIG. 2A, under an embodiment of the invention.

FIG. 2C illustrates an alternative application for use with one or more embodiments described herein.

FIG. 3 illustrates a technique for forming a wireless communication device that integrates VSD material in its electrical components and/or elements, under an embodiment of the invention.

FIG. 4A-FIG. 4E illustrate a process for forming an RFID tag device using VSD material, according to one or more embodiments of the invention.

### DETAILED DESCRIPTION

Embodiments described herein provide for the use of a voltage switchable dielectric material (VSD) material as part of a wireless communication device (such as a tag or chip set). VSD material may be provided as part of the packaging, or integrated or combined with electrical components and elements of a wireless communication device. As provided with one or more embodiments, the integration of VSD material protects the wireless communication device (such as their chips or integrated circuits) from voltage transients such as electrostatic discharge (ESD) and electrical overstress (EOS), as well as moisture, impact and other electrical or mechanical threats.

Examples of wireless communication devices that are applicable to embodiments described herein include RFD tags, cellular communication chips, short-range wireless communication chips and devices (e.g. such as provided under Bluetooth or IEEE 802.11 standards), and other devices that can receive or transmit microwave signals for communication.

As used herein, “voltage switchable material” or “VSD material” is any composition, or combination of compositions, that has a characteristic of being dielectric or non-conductive, unless a voltage is applied to the material that exceeds a characteristic voltage level of the material, in which case the material becomes conductive. Thus, VSD material is a dielectric unless voltage exceeding the characteristic level (e.g. such as provided by ESD events) is applied to the material, in which case the VSD material is conductive. VSD material can also be characterized as any material that can be characterized as a nonlinear resistance material.

Various kinds of VSDM exist. Examples of voltage switchable dielectric materials are provided in references such as U.S. Pat. No. 4,977,357, U.S. Pat. No. 5,068,634, U.S. Pat. No. 5,099,380, U.S. Pat. No. 5,142,263, U.S. Pat. No. 5,189,387, U.S. Pat. No. 5,248,517, U.S. Pat. No. 5,807,509, WO 96/02924, and WO 97/26665. In one implementation, the VSDM material corresponds to material manufactured and sold under the trade name of “SURGX”.

One or more embodiments provide for use of VSD material that includes 30 to 80% insulator, 0.1% to 70% conductor, and 0% to 70% semiconductor. Examples of insulative materials include but not limited to silicone polymers, epoxy, polyimide, polyethylene, polypropylene, polyphenylene oxide, polysulphone, solgel mateterials, creamers, silicone dioxide, aluminum oxide, zirconia oxide, and other metal oxide insulators. Examples of conductive materials include metals such as copper, aluminum, nickel, and stainless steel. Examples of semiconductive material include both organic and inorganic semiconductors. Some inorganic semiconductors include silicon, silicon carbide, boron nitride, aluminum nitride, nickel oxide, zinc oxide, and zinc sulfide. Examples of organic semiconductors include poly-3-hexylthiophene, pentacene, perylene, carbon nanotubes, and C60 fullerenes. The specific formulation and composition may be selected for mechanical and electrical properties that best suit the particular application of the VSD material.

According to an embodiment, a wireless communication device includes a combination of conductive elements that are structured to enable transmission or receipt of wireless signals. A VSD material may be provided with that device that has a characteristic of switching from being dielectric to being conductive when a voltage is applied to the material that exceeds a characteristic voltage level. The VSD material may be positioned to ground at least a portion of the device when a voltage is encountered that exceeds the characteristic voltage level.

In an embodiment, VSD material is integrated into electrical or mechanical components of an RFID device. The VSD material may be provided to protect the device from electrical events such as electrostatic discharge (ESD). According to one embodiment, VSD material partially or fully encapsulates the RFID device.

Additionally, one or more embodiments incorporate VSD material onto an underlying substrate or board on which a wireless communication device (e.g. an RFID device) is provided. The VSD material may also be applied onto a substrate that is subsequently used to form some or all of the remaining device. Ion deposition processes, such as electroplating, may be used to form conductive elements on the substrate while the VSD material is in a conductive state.

Still further, one or more embodiments provide that VSD material is incorporated into the housing, intermediate layer or provided in some other formation that is integral or connected to a wireless communication device.

According to an embodiment, a device is provided for generating radio-frequency identification signals. The device includes a package, a substrate provided within the package, and one or more logic elements that are provided on the substrate. The one or more logic elements may be capable of generating data, including identification data. A transmission component may be provided on the substrate that generates a signal that carries the identification information. The device may also include VSD material provided in the package. The VSD material may be positioned to ground at least a portion of the device when a voltage is encountered that exceeds a characteristic voltage level of the VSD material.

Additionally, one or more embodiments provide that VSD material is used during electroplating or other ion deposition processes for forming conductive elements and components of a wireless communication device. In one embodiment, a substrate is formed to include a layer of VSD material. A layer of resistive material is provided over the layer of VSD material. The resistive material is selectively removed to form a pattern that includes locations that are to underlie electrical components of the wireless communication device. These components may include any one or more of (i) one or more logic elements that are to be embedded in the device, (ii) a wireless communication element (e.g. an antenna), (iii) interconnect elements between the one or more logic elements and the wireless communication element, (iv) a power source, or (v) interconnect elements between the power source and the one or more or more logic elements or the wireless communication element. Once the pattern is formed, a voltage is applied to the substrate that exceeds the characteristic voltage of the VSD material. Concurrently with applying the voltage, the substrate is exposed to conductive material so that conductive material bonds to the VSD material. This results in the formation of conductive traces on the substrate where at least a portion of the pattern is provided.

In particular, one or more embodiments provide that the removal of non-conductive or resistive material is based on identification of locations where specific conductive elements or components of the wireless communication device are to be located. For example, in an RFID device, the select locations may coincide with the location of the antenna element, or the location of traces extending conductivity between the antennal element and the microchip or power source.

Wireless Communication Device with VSD Material

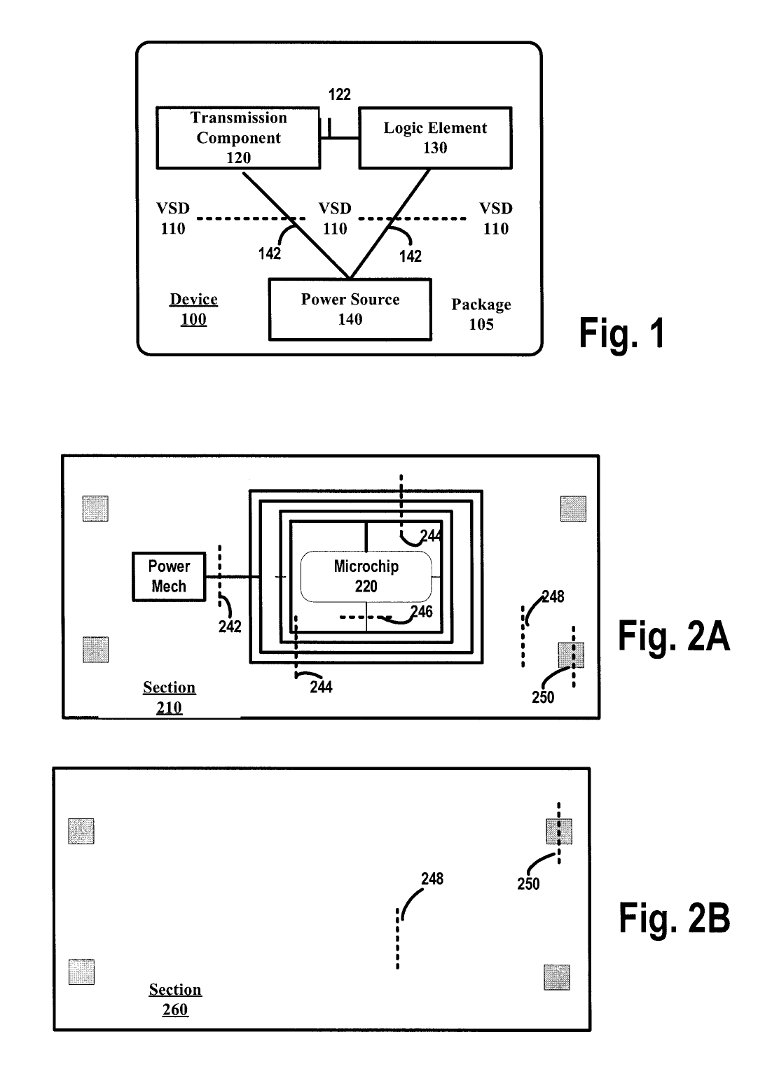

FIG. 1 illustrates a wireless communication device that incorporates or integrates VSD material, under an embodiment of the invention. A wireless communication device such as described by FIG. 1 may correspond to an RFID device, a cellular chip, a short-range radio chip (e.g. Bluetooth or WiFi device) or microwave communication component.

In an embodiment, a device 100 includes a package 105 that contains a communicative element 120, a logic element 130, and a power source 140. The package 105 may not be required in all applications, in cases such as when device 100 is to be combined into the housing of another device (such as a cell phone). The power source 140 may correspond to either an active or passive mechanism to distribute power to the communicative element 120 and the logic element 130 The logic element 130 may correspond to a chip (e.g. microchip), or combination or circuits and devices that can generate data. In, for example, an RFID application, the microchip may generate identification information, and the communicative element 120 is a transmitter that emits a radio-frequency signal that communicates identification information provided by the microchip.

In other wireless device implementations, the communicative element 120 may be an inductive or capacitive element that creates detectable field variations. The logic element 130 may also have more complex logic. For example, in a cellular chip, the logic element may correspond to a processor and associated logic that performs various processes through signals provided from the communicative element 120.

Depending on the type and functionality, other components, such as memory may be included in the package and conductively coupled to the power source 140 and logic elements 130. In an RFID application, for example, the communicative element 120 may correspond to an antenna that can generate a radio-frequency signal that provides the identification information using signal characteristics such as modulation.

If device 100 has an active power source, the power source 140 may include an on-board battery. If device 100 is passive (e.g. passive RFID device), the power source 140 may correspond to a pad or receiver that generates energy from an external signal or application. For example, as a receiver, the power source 140 may be structured to receive radio-frequency signals from other devices, and then generate internal power signals to activate the communicative element 120 and the logic element 130.

An interconnect element 122 may enable identification information and other data to be communicated from the logic element 130 to the communicative element 120. Likewise, power connect elements 142 may distribute power from the power source 140 to the communicative element 120 and/or logic element 130. While the power source 140 is shown as being a discrete component, it may be implemented as a distributed element, or combined with other elements. For example, other elements may be provided with receiver pads to enable those elements and surrounding elements to be energized with application of an external radio-frequency signal.

In an embodiment, VSD material is integrated, incorporated, or otherwise combined with electrical components and elements of the device 100. According to one or more embodiments, VSD material may be integrated or combined with the communicative element 120, the interconnect elements 122 extending conductivity between the communicative element 120 and the logic element 130, and the power connect elements 142. Numerous other locations for VSD material 110 may also exist. For example, the logic element 130 may be integrated or combined with VSD material 110, or positioned on or adjacent to VSD material. Likewise, a receiver comprising power source 140 may be combined or integrated with the VSD material 110. When combined or integrated with electrical components and elements of the device 100, the VSD material 110 may provide protection against ESD events and EOS. Additionally, as described with other embodiments, application of VSD material 110 may be used in electroplating and other metal deposition processes to enable conductive elements that comprise the electrical components and elements of the device 100 to be integrally formed with the VSD material 110.

As an addition or alternative to embodiments described above, VSD material 110 may be combined or integrated into the mechanical structure of the device 100. In an embodiment, the VSD material 100 may form part or all of the composition of the package 105. The VSD material may also form part of other components that serve to encapsulate the various electrical components of the device 100. As an addition or alternative, VSD material 110 may also be used to adhere portions of the package 105. When used with the mechanical structure, the VSD material 110 may provide protection against various events such as those that carry high levels of electrostatic discharge.

RFID Tag with VSD Material

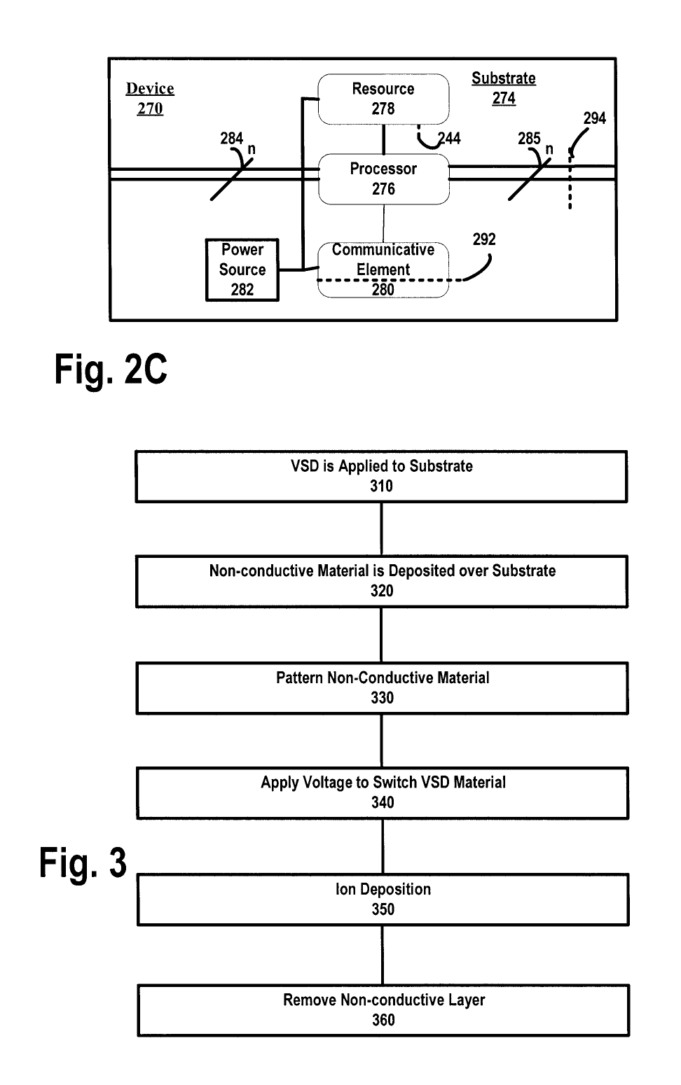

FIG. 2A and FIG. 2B illustrate construction of an RFID device that uses VSD material, under an embodiment of the invention. An embodiment of FIG. 2A illustrates electrical components provided with a first section 210 of the RFID device, while a second section 260 primarily provided encapsulation. Other implementations provide that electrical components and elements are provided on both the sections 210 and 260.

In an embodiment illustrated by FIG. 2A, first section 210 includes a microchip 220 as a logic element, an antenna 224 for a communicative element, and a power source 230. The microchip 220 generates data, including identification information that is specific or characteristic of the RFID device. The antenna 224 may be formed by conductive traces that can exhibit a radio-frequency signal when energized. Interconnect elements 222 may extend conductivity between the microchip 220 and the antenna 224. When the microchip 220 is energized, the microchip may signal the identification information and other data onto the antenna 224, where the data is signaled out for an RFID scanner or reader.

The radio-frequency signal generated by the antenna 224 may have a characteristic (e.g. frequency) that corresponds to the identification information. In an implementation shown, the antenna 224 includes multiple trace elements 225, arranged concentrically. Other arrangements of traces or pads may also be used for antenna 224.

In one implementation, the power source 230 corresponds to an on-board battery that generates a power signal to energize the antenna 224 and the microchip 220. In another implementation, the power source 230 may correspond to a pad, or a distribution of electrical traces and/or resources that can receive and be energized by an externally applied radio-frequency signal. In the latter case, the power source may either be separated or combined with conductive elements that serve other purposes. Conductive leads and traces that extend power from the power source 230 to the other elements and components are referred to as power connect elements 232.

The RFID device formed by the combination of sections 210 and 260 may be provided with VSD material in anyone of numerous locations. Positions 242-250 represent possible locations where VSD material can be integrated into the RFID device, according to one or more embodiments of the invention. Since positions 242-250 are representative of other like positions or regions on the device, discussion of VSD material at any given individual position 242-250 is applicable to a class of locations represented by that one positions.

The positions 242-246 are representative of locations or regions of the RFID device where VSD material may be combined or integrated with electrical elements or components of the RFID device. According to one embodiment, VSD material may be provided at locations represented by position 242. At such locations, VSD material may be combined or integrated with conductive power connect elements 232 that extend conductivity between the power source 230 and other elements of the RFID device.

As an addition or alternative embodiment, VSD material may be provided at locations represented by a position 244. At such locations, the VSD material may be combined or integrated with trace elements 225 that form the antenna 224. In this way, the VSD material may be provided with or as part of the antenna element 224 of the RFID device.

Similarly, VSD material may be provided at locations represented by position 246. At such locations, the VSD material may be combined or integrated with the interconnect elements 222 extending conductivity between the microchip 220 and the antenna 224. Numerous other locations for VSD material may also be provided, according to various other embodiments. For example, VSD material may be provided under or with the microchip 220 or the power source 230.

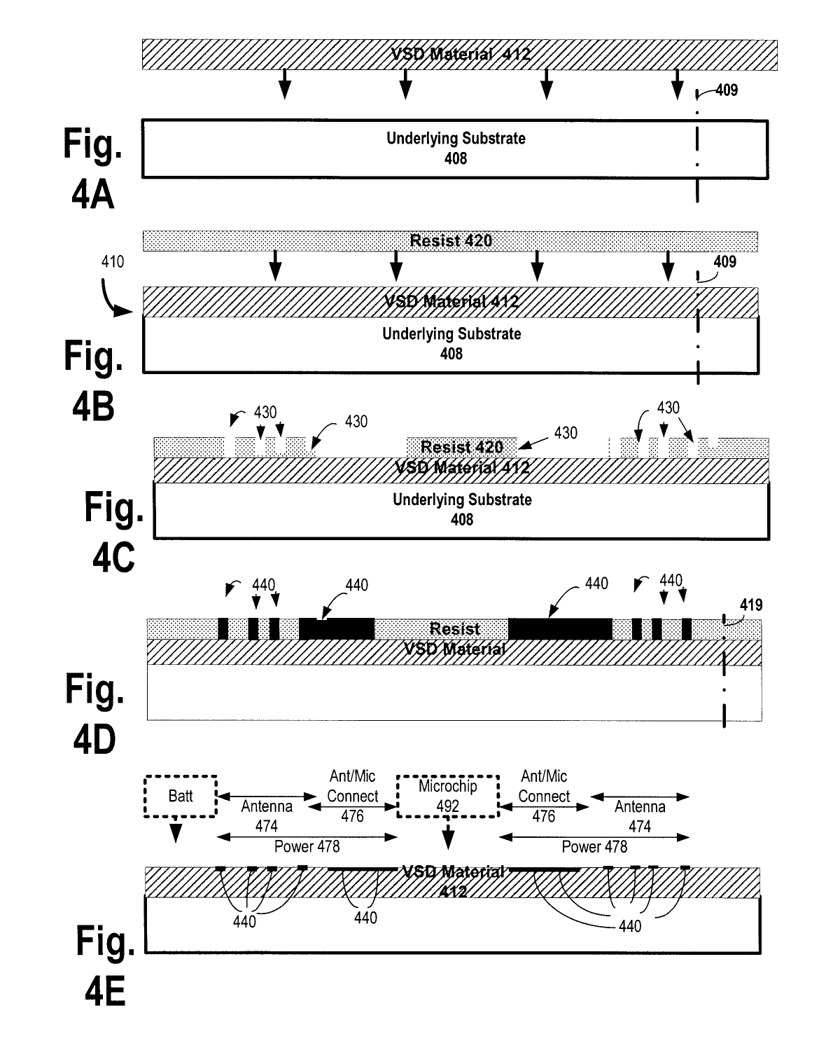

The manner by which VSD material may be combined or integrated with electrical components and elements may vary. In one embodiment, the VSD may be deposited on or adjacent to the electrical component or element (e.g. traces 225 of the antenna 224). Alternatively, as described with embodiments such as described with FIG. 4A-4E, the VSD material may used to form (e.g. by bonding or deposition) the conductive elements provided at the various locations described.

Mechanically, the first section 210 and the second section 260 may be formed from any one of many materials to have physical characteristics that are suited for the application of the RFID device. For example, the sections 210 and 260 may be formed from flexible material to form a casing 202 that is suited for applications where the device may undergo bending or flexing. Alternatively, rigid material may be used to form the casing 202 for other applications where, for example, the device may be struck, dropped or subjected to physical abuse. As an alternative or addition to embodiments in which the VSD is integrated or combined with electrical elements and components, one or more embodiments provide that the VSD material is integrated or combined into mechanical components or aspects of the RFID device. With reference to FIG. 2A and FIG. 2B, VSD material may be provided at locations represented by a position 248. At such positions, the VSD material may be combined or integrated into the casing 202. Alternatively, the VSD material may be provided as a layer or thickness mounted to an underside of the casing, or as a strip extending across either of the section 210, 260. In one embodiment, the formulation of the VSD material may match the physical characteristics or properties of the material used for the casing. For example, the composition of the VSD material may be varied to match that of the casing 202.

With reference to FIG. 2A and FIG. 2B, one or more embodiments also provide that VSD material may be provided at locations represented by position 250 as an adhesive, so as to join the section 210 and 260 together. According to an embodiment, the composition of the VSD material may configured to enhance adhesive properties. When applied to locations represented by positions 250, the VSD material can facilitate adhesion between sections 210 and 260.

FIG. 2C illustrates an alternative application for use with one or more embodiments described herein. In an embodiment of FIG. 2C, a wireless device 270 includes a substrate 274 on which components such as a processor 276 (or chip or other logical element) and other resources 278 (e.g. memory) are located. A communicative element 280 (transmitter/receiver) may also be provided on the substrate 274. The communicative element 280 may generate or receive radio-frequency signals (e.g. such as in the cellular range or in the range defined by IEEE 802.11), or alternatively, provide or detect inductive or capacitive field variations.

Numerous conductive elements, in the form of traces 275 and leads may be distributed to between the processor 276 and the resources 278. A power resource 282, in the form of an on-board battery, or receiver for receiving wireless power transmission, may also be included in the substrate 274. The substrate 274 may also include outbound and inbound communication lines 284,285, to enable signal communications with the processor 276. In one implementation, outbound and inbound communication lines 284, 285 may extend to a connector or port (e.g. flex cable) to enable another processor to receive communications from the processor 276. In one implementation, outbound and inbound communication lines 284, 285 may extend to the wireless communicative element 280 to enable a wireless communication port.

According to one or more embodiments, VSD material may be integrated or incorporated with mechanical or electrical elements of the device 270. A location represented by the position 292 illustrates that VSD material may be incorporated or integrated with the communicative element 280. A location represented by the position 294 illustrates that VSD material may be incorporated or integrated with the outbound or inbound communication lines 284, 285. Additionally, as described with an embodiment of FIG. 2A (RFID application), one or more embodiments may provide for VSD integration or incorporation with various other resources, components and conductive elements of the device 270. For example, VSD material may be integrated or incorporated with (i) the power resource 282 and/or power lines extending from it, or (ii) with the processor 276 and/or conductive traces extending communications between the processor 276 and the communicative element 280 or other resources 278.

As also described an embodiment of FIG. 2A and FIG. 2B, the VSD material may be combined with a housing or other mechanical structure of the device 270. The VSD material may also be combined or substituted for use of adhesives to mechanically retain elements or the housing.

With regard to any of the embodiments described with FIG. 2A-FIG. 2C, the VSD material may be designed or selected to have a characteristic voltage level that is less than a breakdown voltage of the wireless communication device (e.g. RFID tag). In other words, embodiments may provide that the characteristic voltage level of the VSD material is less than a minimum voltage level (e.g. transient voltage from surge) that would cause the wireless communication device to become inoperative.

Device Formation with VSD Material

FIG. 3 illustrates a technique for forming a wireless communication device that integrates VSD material in its electrical components and/or elements, under an embodiment of the invention. A method such as described by FIG. 3 may be used to form devices that transmit signals, including radio-frequency signals (e.g. RFID tags, cellular chips, WiFi/Bluetooth chips etc.), microwave signals, and signals for capacitive or inductive applications.

General techniques for electroplating or forming electrical circuits and components using VSD material are described in the following: U.S. patent application Ser. No. 10/941,226, filed Sep. 14, 2004, entitled “Current Carrying Structure Using Voltage Switchable Dielectric Material,” naming Lex Kosowsky as sole inventor; which is a continuation of U.S. Pat. No. 6,797,145 (formerly U.S. patent application Ser. No. 10/315,496), filed on Dec. 9, 2002 and entitled “Current Carrying Structure Using Voltage Switchable Dielectric Material,” naming Lex Kosowsky as sole inventor; which is a continuation of U.S. patent application Ser. No. 09/437,882, filed on Nov. 10, 1999 and now abandoned; which claims priority to Provisional U.S. Application No. 60/151,188, filed on Aug. 27, 1999, and now expired. All of the aforementioned applications are hereby incorporated by reference in their respective entirety for all purposes.

According to a step 310, VSD material is applied to a substrate or surface on which conductive components and elements are to be provided. The amount of VSD material that may be deposited on the substrate may, depending on the application of the process described, range from between 1 micron to 1000 microns in thickness.

In a step 320, a layer of non-conductive material is provided over the VSD material. For example, photoresist material may be deposited over the VSD material.

Step 330 provides that the non-conductive layer is patterned on the substrate. The patterning exposes regions which coincide in position with the subsequent formation of conductive elements that are to comprise portions of the wireless device. For example, the patterning may be selective to designate exposed regions that are to coincide with formation of transmission elements, including inductive or capacitive elements for sending out signals. In one embodiment, a mask may be applied to the non-conductive layer in order to pattern it. The exposed regions of the pattern coincide with the location of conductive elements or components that are to form the transmission component for the device. For wireless devices such as described with FIG. 1, the exposed regions coincide with where traces for the communicative element are to be provided. As another example, with reference to an embodiment of FIG. 2A and FIG. 2B, the pattern may define the location where the antenna 224 is to be provided for the RFID device. In another implementation, the pattern may define the location where an inductive or capacitive signal communicative element may be provided for various kinds of wireless devices.

In step 340, the VSD material is triggered or switched from being dielectric to being conductive. The VSD material is applied a voltage that exceeds the material's characteristic voltage level. This voltage may be applied either on the thickness that includes the VSD material, or in the portion of the substrate that is underneath the VSD material. In the latter case, the portion of the substrate underneath the VSD material may be conductive (e.g. formed from copper or other metals) so as to carry the charge to the VSD material. Application of the voltage to the conductive substrate may be desired in come cases to avoid linear conductivity by the VSD material in the direction of the substrate. The applied voltage may be steady (e.g. “DC”) or pulsed.

While the VSD material is conductive, step 350 provides that a process is performed to form conductive elements (e.g. traces) within the exposed regions of the pattern. Anyone of many processes may be performed to deposit ionic media into the exposed regions defined by the pattern of the non-conductive layer. In one implementation, an electroplating process is performed, where the substrate, with the VSD material and patterned photoresist material, is submerged into an electrolytic solution.

As alternative implementation, ionic deposition is performed using a powder coating process. In this process, power particles are charged and applied to the exposed regions defined by the pattern. The application of the powder may be accomplished by depositing the powder on the exposed regions, or by submerging the substrate in a powder bath.

Still further, another implementation may use an electro-spray process. Ionic media may be contained in the form of charged particles in a solution. The solution may be applied to the substrate while the VSD material is conductive. The application of the spray may include the use of ink or paint.

Other deposition techniques may also be used for performing ion deposition on the VSD material when in the conductive state, For example, vacuum deposition processes such as physical vapor deposition (PVD) or chemical vapor deposition (CVD) processes. In PVD, metal ions are introduced into a chamber to combine with gas ions. The VSD material on the substrate may be made conductive to have an opposite charge, so as to attract and bond with the ions of the chamber. In CVD, a film of ionic material may be applied to the VSD material on the surface of the substrate.

In step 360, the non-conductive material may (optionally) be removed from the substrate, so as to leave the formed conductive elements. In one implementation, a base solution (e.g. KOH), or water, is applied to the substrate to remove the photoresist material, The conductive elements may correspond to leads, traces and other elements that are positioned to interconnect various components and/or regions of the substrate.

Subsequent to removing the photoresist layer, one or more embodiments provide that a polishing step is performed on the substrate with the formed electrical elements. In one embodiment, a chemical mechanical polish is used to polish the substrate.

The resulting substrate includes electrical elements with inherent ability to handle transient voltages and EOS. In the context of a wireless communication device, a process such as described in FIG. 3 may be used to form trace elements that include the antenna or communicative element of the device, as well as other elements or components. Once the substrate is formed, devices such as micro-chips, memory components and other devices may be mounted onto the board in predetermined positions that coincide with the pattern of conductive components and elements.

Other steps may be performed depending on the application. For example, the substrate with conductive elements may be mounted into a casing. The casing itself may also include additional VSD material. The resulting device may correspond to a transmitter for radio-frequency signals, microwaves, or signals for capacitive/inductive applications.

FIG. 4A-FIG. 4E illustrate a process for forming an RFID device, according to one or more embodiments of the invention. A process such as described with FIG. 4A-FIG. 4E may be performed in order to integrally form VSD material with electrical components and elements of an RFID device. Among other advantages, use of VSD material simplifies the process for forming an RFID process, while at the same time, enabling electrical components or elements of the RFID to have inherent ability to handle EOS or ESD events. In particular, the integration of VSD material into the electrical components of the RFID device enables the VSD material to ground the device when transient voltages are present (such as when ESD events occur).

In a step illustrated by FIG. 4A, a substrate 410 is formed to include VSD material 412. Under one implementation, the VSD material 412 is deposited as a layer over an underlying substrate 408.

Subsequently, FIG. 4B illustrates a step in which a non-conductive layer 420 is deposited on the substrate 410. The non-conductive layer 420 may correspond to, for example, photoresist material.

In a step illustrated by FIG. 4C, the non-conductive layer is patterned to form exposed regions 430. A resulting pattern corresponds to the pattern of conductive elements and components that are to be provided on the RFID device as a result of the formation process being described.

In a step described by FIG. 4D, conductive elements 440 are formed over the exposed regions 430 defined by the pattern formed in a step of FIG. 4C. Under an embodiment, a voltage is applied to the substrate 410 that exceeds the characteristic voltage of the VSD material 412. Application of the voltage results in the VSD material 412 switching from being dielectric to being conductive. Once the VSD material 412 is made conductive with application of the voltage, ionic media is deposited in the exposed regions defined by the pattern to form the electrical elements and components.

In one implementation, ionic media deposition is performed by way of an electroplating process. In the electroplating process, the substrate 410 is submerged in an electrolytic solution, where ionic media from the solution bonds with the VSD material (which is in a conductive state) in the exposed regions defined by the pattern. As a result of this step, conductive material 440 is formed on the substrate 410, and the VSD material 412 underlies the conductive elements or components that will result from the formation of the conductive material 440.

As described with an embodiment of FIG. 3, the underlying substrate 408 may be formed from conductive material, such as a metal. Application of the voltage may occur at a point of contact that coincides with the substrate 408, and not directly with the VSDM material 412. For example, the voltage may be provided underneath the substrate 408. Such application of voltage may be implemented to avoid, for example, linear (i.e. horizontal) conductivity on the VSDM.

As also described, the application of the voltage may be steady or pulsed.

Alternative ionic media deposition processes may be performed. For example, as described with an embodiment of FIG. 3, a powder coating process may be used to deposit charged powder particles into the exposed regions defined by the pattern. Alternatively, an electro-spray may force ionic media in a solution to bond and form electrical material in the exposed regions defined by the pattern.

In a step of FIG. 4E, the non-conductive layer 420 is removed and the conductive elements 440 or polished or are otherwise reduced on the substrate to form some or all of the trace, leads and components of the RFID device. The removal of the non-conductive layer 420 may be omitted in some applications where it is desirable to maintain a layer of such material.

FIG. 4E illustrates how components and elements of the RFID device may be formed as a result of a process described. In an embodiment, the VSD material 412 is integrated with and underlies trace elements that, for example, (i) form an antenna 474 of the RFID device, and (ii) form the interconnect 476 that extend conductivity between the microchip 492 and the antenna 474. One or more embodiments may also provide that VSD material 412 underlies trace elements that underlie a battery 494, or trace elements 478 that extend power from the battery 494 to the antenna 474 and/or to microchip 492.

An embodiment such as described by FIG. 4A-4E enables creation of electrical components and elements within the RFID device that overlay VSD material, and as such, include inherent capabilities to ground transient voltages that may result from, for example, ESD. The RFID may also be created using fewer fabrication steps, as compared to more conventional techniques.

While embodiments such as described with FIG. 4A-4E and elsewhere in this application describe use of VSD material, one or more embodiments provide that different compositions and formulations of VSD material for use on a single RFID device. For example, the application of VSD material 412 onto a substrate (FIG. 4A) may include application of multiple VSD material, each with a different composition. This allows the design of the RFID device to utilize VSD materials with mechanical or electrical characteristics that are best suited for a particular electrical component or element. For example, it may be desirable to provide regions near a battery of the RFID device with VSD material that has a higher characteristic voltage level than regions near the microchip 492, as the microchip may be more sensitive to surges, or the battery may provide larger voltage spikes.

Other components that may be provided on the substrate include light-emitting devices, such as LEDs and OLEDs. As described in U.S. Provisional Patent Application No. 60/740,961, LEDs and OLEDs may also be susceptible to breakdown as a result of transient voltages. One or more embodiments provide for trace elements formed on the substrate to provide for leads and interconnects to light-emitting devices. The VSD material selected for use may have a characteristic voltage level that is less than the conductive elements and components of both the RFID device and the light-emitting devices.

While FIG. 4A-FIG. 4E are specific to the creation of an RFID device, any wireless communication device such as described with other embodiments of this application may be created or formed in part through processes such as described in FIG. 4A-4E. For each alternative application, the location of conductive elements and components may determine photoresist (or non-conductive layer) patterns.

Moreover, with regard to any of the embodiments described, the wireless communication devices may be multi-dimensional. For example, components for an RFID device or other communication element may be incorporated on both sides of a substrate, and then conductively interconnected through use of one or more vias. The creation of a conductive vias may be performed in any one of many conventional techniques. Alternatively, one or more embodiments provide for formation of a vias on a substrate such as shown in embodiments of FIG. 4A-4E as follows: (i) drill or form a hole 409 that extends through the substrate 408 (FIG. 4A); (ii) when applying VSD material, extend VSD material into the vias 409; (iii) when patterning the photoresist, form the pattern so that a path is formed for conductive trace elements to extend to a boundary of the hole 409; (iv) perform ionic deposition so that the vias is surfaced with conductive material, forming conductive or operational vias 419; and (v) repeat the process described to accommodate electrical elements and components on the opposing side of the substrate. A process for forming plated vias 419 using VSD material is described in more detail with U.S. Pat. No. 6,797,145, which is incorporated by reference in its entirety by this application.

In addition to two sided substrates, vias may extend conductivity to multiple conductive layers for a suitable designed substrate. For example, some substrates include intermediate thickness layers that include electrical components and elements. Vias may extend to connect to such layers embedded in the overall thickness of the substrate.

### ALTERNATIVE EMBODIMENTS AND IMPLEMENTATIONS

While embodiments described herein provide for devices (wireless communication devices, RFID tags), embodiments may also include an antenna, or capacitive or inductive field element that is formed with use of VSD material. Such communication components may be added to devices such as chip sets and RFID tags, independently of the formation of the remainder of that device. For example, an antenna for an RFID tag may be formed as a separate part, and combined with the RFID tag during an assembly step.

### CONCLUSION

Although illustrative embodiments of the invention have been described in detail herein with reference to the accompanying drawings, it is to be understood that the invention is not limited to those precise embodiments. As such, many modifications and variations will be apparent to practitioners skilled in this art. Accordingly, it is intended that the scope of the invention be defined by the following claims and their equivalents. Furthermore, it is contemplated that a particular feature described either individually or as part of an embodiment can be combined with other individually described features, or parts of other embodiments, even if the other features and embodiments make no mentioned of the particular feature. This, the absence of describing combinations should not preclude the inventor from claiming rights to such combinations.

1. A wireless communication device comprising:
a plurality of electrical components;
a protective mechanism comprising a voltage switchable dielectric (VSD) material that is capable of switching from being insulative to carrying current generated from a transient voltage that exceeds a threshold voltage level;
wherein the mechanism is adapted to enable the VSD material to switch and carry current from the transient voltage such that the wireless communication device is not subjected to a minimum voltage level that would otherwise cause the wireless communication device to become inoperative.

2. The device of claim 1, wherein the VSD material is positioned to ground the plurality of electrical components when the voltage is encountered that exceeds the threshold voltage level.

3. The device of claim 1, further comprising:
a substrate on which the plurality of electrical elements is provided, the plurality of electrical components including one or more logic elements; and
wherein the VSD material is provided to ground the one or more logic elements.

4-5. (canceled)

6. The device of claim 1, further comprising a package that encapsulates the plurality of electrical components, and wherein the VSD material is provided as part of the package.

7. The device of claim 6, wherein the VSD material is provided as at least one of (i) on a portion of the package, or (ii) an adhesive to bind one or more portions of the package or its components.

8-26. (canceled)

27. The device of claim 1, wherein the VSD material comprises 30% to 80% insulator, 0.1% to 70% conductor, and 0% to 70% semiconductor.

28. The device of claim 1, wherein the VSD material comprises a polymer.

29. The device of claim 1, wherein the VSD material comprises a concentration of carbon nanotubes.

30. The device of claim 1, further comprising:
a substrate on which the plurality of electrical components are provided, the plurality of electrical components including an antenna and a processor; and
wherein the VSD material is provided as a layer to ground the antenna and the processor.
